(19) United States
(12) Patent Application Publication
(10) Pub. No.: US 2024/0396305 A1
(43) Pub. Date: Nov. 28, 2024

(54) LIGHT EMITTING DEVICE AND PROJECTOR

(71) Applicant: SEIKO EPSON CORPORATION, Tokyo (JP)

(72) Inventor: Masamitsu MOCHIZUKI, Chino-shi (JP)

(73) Assignee: SEIKO EPSON CORPORATION, Tokyo (JP)

(21) Appl. No.: 18/670,917

(22) Filed: May 22, 2024

(30) Foreign Application Priority Data
May 23, 2023 (JP) 2023-084457

(51) Int. Cl. H01S 5/22; G03B 21/20; H01S 5/30

(52) U.S. Cl. CPC H01S 5/2226; G03B 21/2033; H01S 5/3013

(57) ABSTRACT

A light emitting device includes a light emitting waveguide layer including a first semiconductor portion and a second semiconductor portion having a conductive type different from the first semiconductor portion, and forming a pn junction with the first semiconductor portion, an electrode being provided to the second semiconductor portion on a side opposite to the first semiconductor portion and injecting an electric current into the pn junction, and at least one optical portion, wherein the light emitting waveguide layer has a longitudinal direction in a first direction, the light emitting waveguide layer generates, at the pn junction, light having an energy smaller than a band gap energy of the semiconductors constituting the first semiconductor portion and the second semiconductor portion, and causes the light being generated to resonate in the first direction, and the optical portion emits the resonating light to a second direction intersecting with the first direction.

The present application is based on, and claims priority from JP Application Serial Number 2023-084457, filed May 23, 2023, the disclosure of which is hereby incorporated by reference herein in its entirety.

### BACKGROUND

### 1. Technical Field

The present disclosure relates to a light emitting device and a projector.

### 2. Related Art

A light emitting device such as a semiconductor laser is used as a light source of a projector or the like.

For example, JP-A-2023-40799 describes a non-classical light source device including a semiconductor structure body including a first semiconductor region of one conductive type selected from a p-type and an n-type, a second semiconductor region of the other conductive type selected from a p-type and an n-type, a pn junction positioned between the first semiconductor region and the second semiconductor region, and a plurality of light emitting regions that are discretely distributed along the pn junction and each emit non-classical light.

In the light source device described above, it is desired to improve light emittance efficiency.

### SUMMARY

A light emitting device according to one aspect of the present disclosure includes a light emitting waveguide layer including a first semiconductor portion being configured by an indirect transition semiconductor and a second semiconductor portion being configured by an indirect transition semiconductor, having a conductive type different from the first semiconductor portion, and forming a pn junction with the first semiconductor portion, an electrode being provided to the second semiconductor portion on a side opposite to the first semiconductor portion and injecting an electric current into the pn junction, and at least one optical portion, wherein the light emitting waveguide layer has a longitudinal direction in a first direction, the light emitting waveguide layer generates, at the pn junction, light having an energy smaller than a band gap energy of the semiconductors constituting the first semiconductor portion and the second semiconductor portion, and causes the light being generated to resonate in the first direction, and the optical portion emits the resonating light to a second direction intersecting with the first direction.

A projector according to one aspect of the present disclosure includes the light emitting device according to one aspect.

### BRIEF DESCRIPTION OF THE DRAWINGS

FIG. 1 is a perspective view schematically illustrating a light emitting device according to the embodiment.

FIG. 2 is a cross-sectional view schematically illustrating the light emitting device according to the embodiment.

FIG. 3 is a view schematically illustrating an optical portion if the light emitting device according to the embodiment.

FIG. 4 is a cross-sectional view schematically illustrating a manufacturing step of the light emitting device according to the embodiment.

FIG. 5 is a perspective view schematically illustrating the manufacturing step of the light emitting device according to the embodiment.

FIG. 6 is a perspective view schematically illustrating a light emitting device according to a first modification example of the embodiment.

FIG. 7 is a perspective view schematically illustrating a light emitting device according to a second modification example of the embodiment.

FIG. 8 is a perspective view schematically illustrating the light emitting device according to the second modification example of the embodiment.

FIG. 9 is a perspective view schematically illustrating a light source module according to the embodiment.

FIG. 10 is a view schematically illustrating a projector according to the embodiment.

FIG. 11 is a cross-sectional view schematically illustrating a light emitting mechanism of the projector according to the embodiment.

FIG. 12 is a view schematically illustrating the projector according to the embodiment.

FIG. 13 is a view schematically illustrating a projector according to a modification example of the embodiment.

### DESCRIPTION OF EMBODIMENTS

A preferred embodiment of the present disclosure is described in detail below with reference to the drawings. Note that the embodiment described below do not unduly limit the content of the present disclosure described in the claims. In addition, not all the configurations described below are essential constituent elements of the present disclosure.

### 1. LIGHT EMITTING DEVICE

### 1.1. Configuration

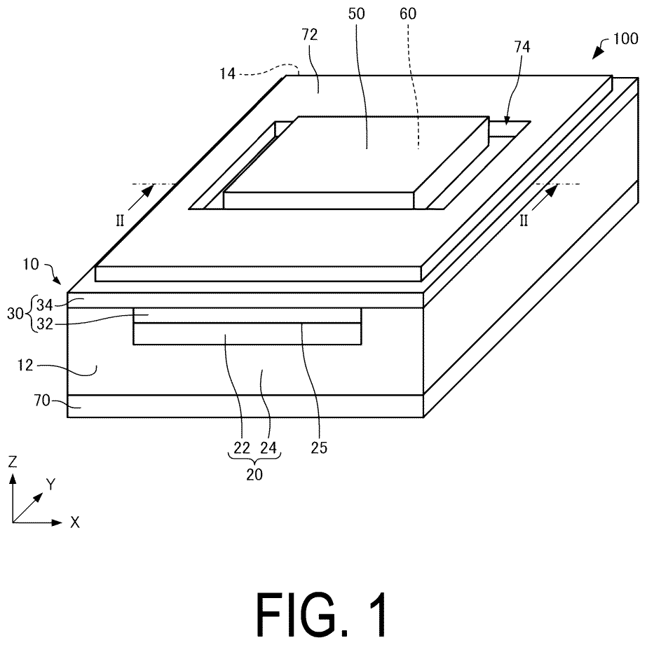

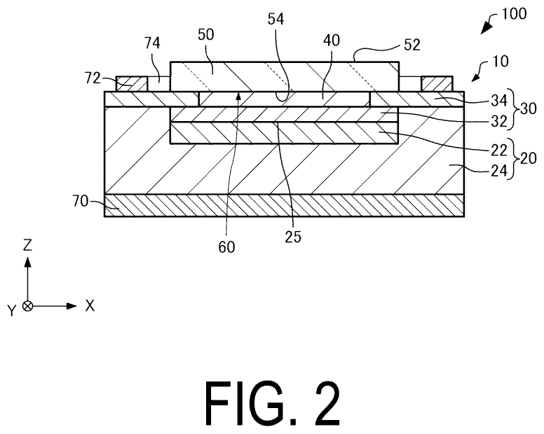

First, a light emitting device according to the embodiment is described with reference to the drawings. FIG. 1 is a perspective view schematically illustrating a light emitting device 100 according to the embodiment. FIG. 2 is a cross-sectional view taken along the line II-II in FIG. 1, which schematically illustrates the light emitting device 100 according to the embodiment. Note that, in FIG. 1 and FIG. 2, an X axis, a Y axis, and a Z axis are illustrated as three axes orthogonal to one another.

As illustrate in FIG. 1 and FIG. 2, for example, the light emitting device 100 includes a light emitting waveguide layer 10, a cover layer 50, an optical portion 60, a first electrode 70, and a second electrode 72. The light emitting device 100 is, for example, a semiconductor laser.

As illustrated in FIG. 1, the light emitting waveguide layer 10 has a longitudinal direction in a first direction. In the illustrated example, the light emitting waveguide layer 10 has a longitudinal direction in the Y-axis direction. For example, the shape of the light emitting waveguide layer 10 is a rectangular parallelepiped shape. The light emitting waveguide layer 10 includes a first side surface 12 and a second side surface 14. The first side surface 12 and the second side surface 14 are end surfaces of the light emitting waveguide layer 10 in the Y-axis direction. In the illustrated example, the first side surface 12 and the second side surface 14 are parallel to each other.

For example, as illustrated in FIG. 2, the light emitting waveguide layer 10 includes a first semiconductor portion 20, a second semiconductor portion 30, and a third semiconductor portion 40.

The first semiconductor portion 20 is provided from the first side surface 12 to the second side surface 14. The first semiconductor portion 20 is configured by an indirect transition semiconductor. The material of the first semiconductor portion 20 is Si, SiC, GaP, ZnO, or the like. SiC may be 4H-SiC or 6H-SiC. The first semiconductor portion 20 has an n-type conductive type, for example. For example, the first semiconductor portion 20 is configured by a semiconductor doped with impurities such as nitrogen (N) and phosphorus (P).

For example, the first semiconductor portion 20 includes a first layer 22 and a second layer 24.

The first layer 22 of the first semiconductor portion 20 is provided between the second layer 24 and the second semiconductor portion 30. The first layer 22 contacts with the second semiconductor portion 30.

The second layer 24 of the first semiconductor portion 20 is provided between the first electrode 70 and the first layer 22. In the illustrated example, the second layer 24 is provided to sandwich the first layer 22 as viewed in the Z-axis direction. The Z-axis direction is a stacking direction of the first semiconductor portion 20 and the second semiconductor portion 30. The impurity concentration of the second layer 24 is lower than the impurity concentration of the first layer 22. It can be confirmed that the impurity concentration of the second layer 24 is lower than the impurity concentration of the first layer 22, by the atom probe analysis, a relationship between an impurity concentration and electric resistivity, or the like. The impurity concentration or the depth can be designed by an energy or a dosage of ion injection, for example. Thus, it can also be confirmed by those in the designing process.

The second semiconductor portion 30 is provided at the first semiconductor portion 20. The second semiconductor portion 30 is provided from the first side surface 12 to the second side surface 14. The second semiconductor portion 30 is configured by an indirect transition semiconductor. The material of the second semiconductor portion 30 is Si, SiC, GaP, ZnO, or the like. The second semiconductor portion 30 has a conductive type different from the first semiconductor portion 20. The second semiconductor portion 30 has a p-type conductive type, for example. For example, the second semiconductor portion 30 is configured by a semiconductor doped with impurities boron (B) and aluminum (Al).

For example, the second semiconductor portion 30 includes a third layer 32 and a fourth layer 34.

The third layer 32 of the second semiconductor portion 30 is provided between the first layer 22 and the third semiconductor portion 40.

The fourth layer 34 of the second semiconductor portion 30 is provided at the second layer 24 and the third layer 32. The fourth layer 34 surrounds the third semiconductor portion 40 as viewed in the Z-axis direction. For example, the fourth layer 34 contacts with the second electrode 72. The impurity concentration of the fourth layer 34 may be higher than the impurity concentration of the third layer 32. The impurity concentration of the upper surface of the fourth layer 34 may be higher than the impurity concentration of the third layer 32. With this, the contact resistance between the second semiconductor portion 30 and the second electrode 72 can be reduced.

Note that, in the illustrated example, the lower surface of the third layer 32 and the lower surface of the fourth layer 34 are not flush with each other. However, the fourth layer 34 may have a thick portion so that the lower surface of the third layer 32 and the lower surface of the fourth layer 34 are flush with each other.

The second semiconductor portion 30 contacts with the first semiconductor portion 20. In the illustrated example, the third layer 32 of the second semiconductor portion 30 contacts with the first layer 22 of the first semiconductor portion 20. The second semiconductor portion 30 forms a pn junction 25 with the first semiconductor portion 20. In the illustrated example, the first layer 22 and the third layer 32 form the pn junction 25.

The third semiconductor portion 40 is provided between the second semiconductor portion 30 and the cover layer 50. In the illustrated example, the third semiconductor portion 40 is provided between the third layer 32 and the cover layer 50. The third semiconductor portion 40 is provided at the third layer 32. The third semiconductor portion 40 is surrounded by the fourth layer 34 as viewed in the Z-axis direction. The third semiconductor portion 40 is configured by an indirect transition semiconductor. The material of the third semiconductor portion 40 is Si, SiC, GaP, ZnO, or the like. The impurity concentration of the third semiconductor portion 40 is lower than the impurity concentration of the second semiconductor portion 30.

The cover layer 50 covers the light emitting waveguide layer 10. The cover layer 50 is provided at the fourth layer 34 of the second semiconductor portion 30 and the third semiconductor portion 40. The cover layer 50 is provided to an opening portion 74 formed in the second electrode 72. The material of the cover layer 50 is SiO₂, SiN, HfO₂, Al₂O₃, Ta₂O₅, or the like. The cover layer 50 transmits the light generated at the pn junction 25.

An upper surface 52 of the cover layer 50 may be provided with a plurality of fine irregular structures. With this, total reflection at the upper surface 52 of the cover layer 50 can be suppressed, and light extraction efficiency can be improved. Note that a lower surface 54 of the cover layer 50 may also be provided with a plurality of fine irregular structures.

The optical portion 60 is provided to the cover layer 50, for example. The optical portion 60 emits light, which resonates in the light emitting waveguide layer 10, to a second direction intersecting with the first direction. The second direction is the Y-axis direction, for example. Note that the second direction may be a direction inclined with respect to the Y-axis direction. The optical portion 60 is an upward-reflection portion that reflects the light, which resonates in the light emitting waveguide layer 10, upward.

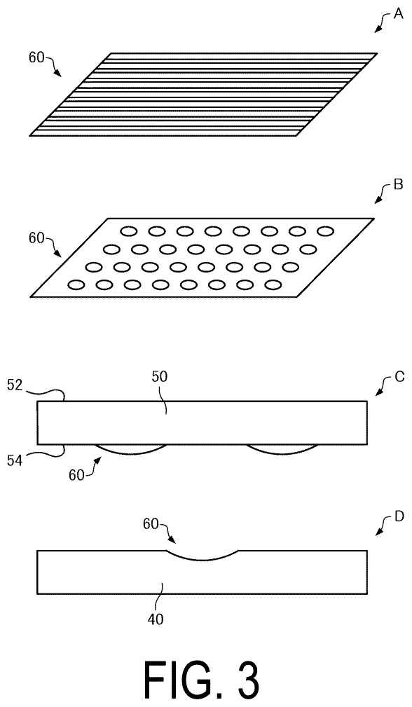

The configuration of the optical portion 60 is not particularly limited as long as the light, which resonates in the light emitting waveguide layer 10, can be emitted to the second direction. Here, FIG. 3 is a view schematically illustrating the optical portion 60. As illustrated in the part A of FIG. 3, the optical portion 60 may be a grating formed at the cover layer 50. The grating may be formed at the upper surface 52 of the cover layer 50, or may be formed at the lower surface 54. Alternatively, as illustrated in the part B of FIG. 3, the optical portion 60 may be a two-dimensional photonic crystal. The two-dimensional photonic crystal may be formed at the upper surface 52 of the cover layer 50, or may be formed at the lower surface 54. Alternatively, as illustrated in the part C of FIG. 3, the optical portion 60 may be a protruding portion provided to the lower surface 54 of the cover layer 50.

Note that the optical portion 60 may not be provided to the cover layer 50 as long as the light, which resonates in the light emitting waveguide layer 10, can be emitted to the second direction. As illustrated in the part D of FIG. 3, the optical portion 60 may be a recessed portion provided in the third semiconductor portion 40, for example.

As illustrated in FIG. 1 and FIG. 2, the first electrode 70 is provided below the first semiconductor portion 20. The second layer 24 of the first semiconductor portion 20 may be in ohmic contact with the first electrode 70. The first electrode 70 is electrically coupled to the first semiconductor portion 20. In the illustrated example, the first electrode 70 is electrically coupled to the first layer 22 via the second layer 24. The material of the first electrode 70 is Ni or Au, for example. The first electrode 70 is one electrode for injecting an electric current into the pn junction 25.

The second electrode 72 is provided at the second semiconductor portion 30. The second electrode 72 is provided to the second semiconductor portion 30 on a side opposite to the first semiconductor portion 20. In the illustrated example, the second electrode 72 is provided at the fourth layer 34. The second electrode 72 is electrically coupled to the second semiconductor portion 30. In the illustrated example, the second electrode 72 is electrically coupled to the third layer 32 via the fourth layer 34. The material of the second electrode 72 is Al, for example. The second electrode 72 is the other electrode for injecting an electric current into the pn junction 25.

The opening portion 74 is provided to the second electrode 72. The opening portion 74 passes through the second electrode 72 in the Z-axis direction. The opening portion 74 causes the light, which is caused to advance in the second direction by the optical portion 60 to pass therethrough.

### 1.2. Operations

In the light emitting device 100, when the first electrode 70 and the second electrode 72 apply a forward voltage to the pn junction 25, a dressed photon-phonon is generated at a dopant pair such as boron in the third layer 32 of the second semiconductor portion 30. With this, the pn junction 25 emits a photon. In other words, the light emitting waveguide layer 10 generates, at the pn junction 25, light having an energy smaller than a band gap energy of the semiconductors constituting the first semiconductor portion 20 and the second semiconductor portion 30. When the semiconductors constituting the first semiconductor portion 20 and the second semiconductor portion 30 are Si, the light emitting waveguide layer 10 generates infrared light. When the semiconductors constituting the first semiconductor portion 20 and the second semiconductor portion 30 are SiC, the light emitting waveguide layer 10 generates visible light. When the semiconductors constituting the first semiconductor portion 20 and the second semiconductor portion 30 are GaP, the light emitting waveguide layer 10 generates red light.

When one dopant pair emits a photon, another dopant pair is also induced by the emitted photon to emit a photon. Further, due to the induced emission, the light being generated is guided through the light emitting waveguide layer 10. The light being guided is multi-reflected between the first side surface 12 and the second side surface 14 of the light emitting waveguide layer 10, resonates in the first direction, and performs laser oscillation. In this manner, the light emitting waveguide layer 10 causes the light being generated to resonate in the first direction. The resonating light is emitted to the second direction by the optical portion 60.

Here, the dressed photon is considered as a virtual photon indicating an interaction state between an electron-hole pair present in the semiconductor and a photon. For example, the dressed photon is present as a dressed photon-phonon via a phonon indicating a photon oscillation in a crystal of the semiconductor, particularly, a coherent phonon. When the dressed photon-phonon breaks into a photon and a phonon, the momentum of the photon has an uncertainty component associated with the phonon. Thus, the momentum of the photon becomes larger as the momentum of the photon corresponds to the momentum of the phonon. Therefore, even in a case of the indirect transition semiconductors, the dressed photon-phonon can compensate a momentum difference between a maximum energy of a valence band and a minimum energy of a conductor, and light having an energy smaller than the band gap energy of the indirect transition semiconductors can be emitted.

For example, the coherent phonon can be present stably due to a dopant pair configured by impurities with which the semiconductor is doped. The dopant pair is formed by a dressed photon phonon-assisted annealing (DPP annealing), which is described later.

### 1.3. Effects

In the light emitting device 100, the light emitting waveguide layer 10 includes the first semiconductor portion 20 and the second semiconductor portion 30. The first semiconductor portion 20 is configured by an indirect transition semiconductor. The second semiconductor portion 30 is configured by an indirect transition semiconductor, has a conductive type different from the first semiconductor portion 20, and forms the pn junction 25 with the first semiconductor portion 20. Further, the light emitting device 100 includes the second electrode 72 and at least one optical portion 60. The second electrode 72 is provided to the second semiconductor portion 30 on a side opposite to the first semiconductor portion 20, and injects an electric current into the pn junction 25. The light emitting waveguide layer 10 has a longitudinal direction in the first direction. The light emitting waveguide layer 10, at the pn junction 25, light having an energy smaller than a band gap energy of the semiconductors constituting the first semiconductor portion 20 and the second semiconductor portion 30, and causes the light being generated to resonate in the first direction. The optical portion 60 emits the resonating light to the second direction intersecting with the first direction.

Thus, for example, as compared to a case in which the light being generated is not caused to resonate in the first direction, the light being generated can obtain a larger gain in the light emitting device 100. With this, the light emitting device 100 can improve light emittance efficiency.

In the light emitting device 100, the second electrode 72 is provided with at least one opening portion 74 through which the light advancing in the second direction passes. Thus, for example, as compared to a case in which the opening portion is not provided, the loss of light caused by the second electrode 72 can be reduced in the light emitting device 100.

The light emitting device 100 includes the cover layer 50 that is provided to the opening portion 74 and covers the light emitting waveguide layer 10. Thus, in the light emitting device 100, the cover layer 50 can protect the light emitting waveguide layer 10 from moisture or the like.

In the light emitting device 100, the optical portion 60 is provided to the cover layer 50. Thus, for example, as compared to a case in which the optical portion is provided to the light emitting waveguide layer, the loss of light guided through the light emitting waveguide layer 10, which is caused by the optical portion 60, can be reduced in the light emitting device 100.

In the light emitting device 100, the first semiconductor portion 20 includes the first layer 22 and the second layer 24 having an impurity concentration lower than the first layer 22. The first layer 22 is provided between the second layer 24 and the second semiconductor portion 30, and forms the pn junction 25. Thus, for example, as compared to a case in which the impurity concentration of the second layer is equal to or higher than the impurity concentration of the first layer, the loss of light guided through the light emitting waveguide layer 10, which is caused by the second layer 24, can be reduced in the light emitting device 100. In the semiconductor, the loss of light is more significant as the impurity concentration is higher. In particular, this tendency is pronounced in SiC.

In the light emitting device 100, for example, the semiconductors constituting the first semiconductor portion 20 and the second semiconductor portion 30 are Si, and the light emitting waveguide layer 10 generates infrared light. Thus, with the light emitting device 100, infrared light can be emitted. Further, for example, Si has better crystalline quality as compared to a III-V compound semiconductor. Thus, the loss of light guided through the light emitting waveguide layer 10 can be reduced.

In the light emitting device 100, for example, the semiconductors constituting the first semiconductor portion 20 and the second semiconductor portion 30 are SiC, and the light emitting waveguide layer 10 generates visible light. Thus, with the light emitting device 100, visible light can be emitted. Therefore, the light emitting device 100 is used as a light source of a projector, for example.

In the light emitting device 100, for example, the semiconductors constituting the first semiconductor portion 20 and the second semiconductor portion 30 are GaP, and the light emitting waveguide layer 10 generates red light. Thus, with the light emitting device 100, red light can be emitted.

In the light emitting device 100, the light emitting waveguide layer 10 includes the third semiconductor portion 40 provided between the second semiconductor portion 30 and the cover layer 50. The impurity concentration of the third semiconductor portion 40 is lower than the impurity concentration of the second semiconductor portion 30. Thus, for example, as compared to a case in which the impurity concentration of the third semiconductor portion is equal to or higher than the impurity concentration of the second semiconductor portion, the loss of light caused by the third semiconductor portion 40 can be reduced in the light emitting device 100.

### 2. METHOD OF MANUFACTURING LIGHT EMITTING DEVICE

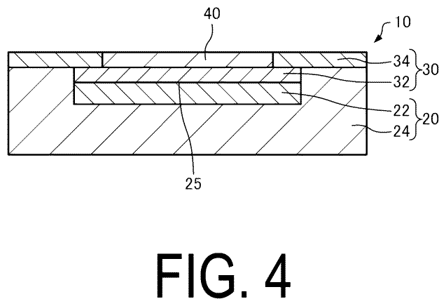

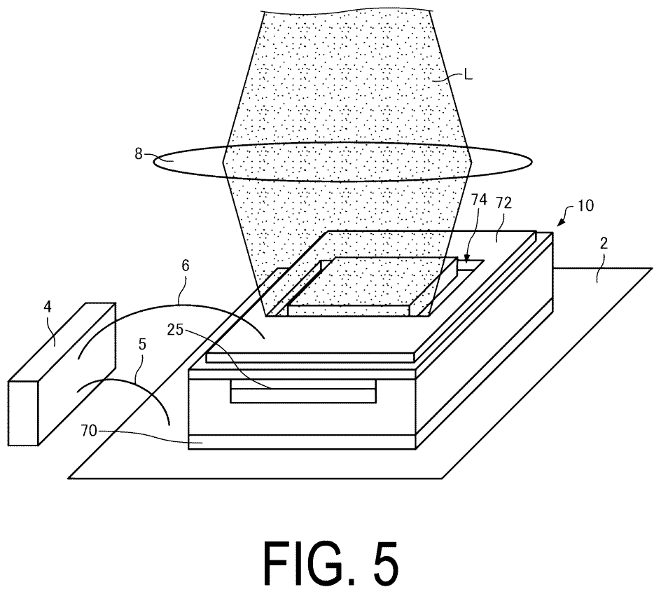

Next, a method of manufacturing the light emitting device 100 according to the embodiment is described with reference to the drawings. FIG. 4 is a cross-sectional view schematically illustrating a manufacturing step of the light emitting device 100 according to the embodiment. FIG. 5 is a perspective view schematically illustrating the manufacturing step of the light emitting device 100 according to the embodiment.

As illustrated in FIG. 4, by the ion injection method, the second layer 24 is doped with impurities to form the first layer 22. By performing this step, the first semiconductor portion 20 including the first layer 22 and the second layer 24 can be formed.

Subsequently, by the ion injection method, the first semiconductor portion 20 is doped with impurities to form the third layer 32. Subsequently, by the ion injection method, the first semiconductor portion 20 is doped with impurities to form the fourth layer 34. By performing this step, the second semiconductor portion 30 including the third layer 32 and the fourth layer 34 can be formed. The region surrounded by the fourth layer 34 is the third semiconductor portion 40. With this, the light emitting waveguide layer 10 including the first semiconductor portion 20, the second semiconductor portion 30, and the third semiconductor portion 40 can be formed.

Note that the first semiconductor portion 20, the second semiconductor portion 30, and the third semiconductor portion 40 may be formed by a vapor growth method such as a metal organic chemical vapor deposition (MOCVD) method and a molecular beam epitaxy (MBE) method, instead of the ion injection method. With this, for example, the third semiconductor portion 40 can be configured by a u-type semiconductor. The u-type semiconductor is an undoped-type semiconductor that is not doped with impurities intentionally. The third semiconductor portion 40 may be configured by an i-type semiconductor formed of an intrinsic semiconductor. Further, for example, the first layer 22 may be an n-type SiC layer, and the second layer 24 may be an i-type Si layer.

As illustrated in FIG. 2, the first electrode 70 is formed below the light emitting waveguide layer 10. Subsequently, the second electrode 72 is formed at the light emitting waveguide layer 10. Subsequently, the second electrode 72 is subjected to patterning to form the opening portion 74. The first electrode 70 and the second electrode 72 are formed by a sputtering method, a vacuum deposition method, or the like. The patterning is performed by, for example, photolithography and etching. Note that the order of forming the first electrode 70 and the second electrode 72 is not particularly limited.

Subsequently, at the light emitting waveguide layer 10, the cover layer 50 is formed in the opening portion 74. The cover layer 50 is formed by a sputtering method, a chemical vapor deposition (CVD) method, a vacuum deposition method, or the like.

Subsequently, the optical portion 60 is formed at the cover layer 50. For example, the optical portion 60 is formed by subjecting the cover layer 50 to patterning. The patterning is performed by, for example, photolithography and etching.

As illustrated in FIG. 5, DPP annealing is performed. While applying a forward electric current to the pn junction 25 of the light emitting waveguide layer 10, the light emitting waveguide layer 10 is irradiated with light L. The wavelength of the light L is the same as, for example, the wavelength of the light generated in the light emitting waveguide layer 10. The light L may be laser light. The temperature is a room temperature, for example.

Conduction caused by DPP annealing generates Joule heat in the light emitting waveguide layer 10. Due to the generated Joule heat, the impurities such as boron are thermally diffused in the second semiconductor portion 30. Further, with irradiation with the light, dressed photons and dressed photon-phonons are generated at positions corresponding to the impurities of the second semiconductor portion 30. Further, due to population inversion caused by a forward electric current, light having an energy corresponding to the peak energy of the light L is emission-induced. With the emission induction, the impurities in the second semiconductor portion 30 lose an energy, and dopant pairs are formed. It is considered that the dopant pairs are distributed along the pn junction 25 in a self-organized manner.

In the illustrated example, the light emitting waveguide layer 10 is placed on a conductive sheet 2 via the first electrode 70. A power source 4 is electrically coupled to the first electrode 70 via a first wire 5 and the conductive sheet 2. Further, the power source 4 is electrically coupled to the second electrode 72 via a second wire 6. The light L from a light source, which is omitted in illustration, is concentrated at a lens 8, and the light emitting waveguide layer 10 is irradiated therewith. The duration of conduction caused by DPP annealing, the electric current amount, and the intensity of the light L are inspected as appropriate so that the number of electrons and the number of dressed photons are substantially equivalent in a one-to-one relationship, for example. Note that irradiation with the light L may be performed from the side surface 12 or 14 side.

The light emitting device 100 can be manufactured through the above-described steps.

### 3. MODIFICATION EXAMPLES OF LIGHT EMITTING DEVICE

### 3.1. First Modification Example

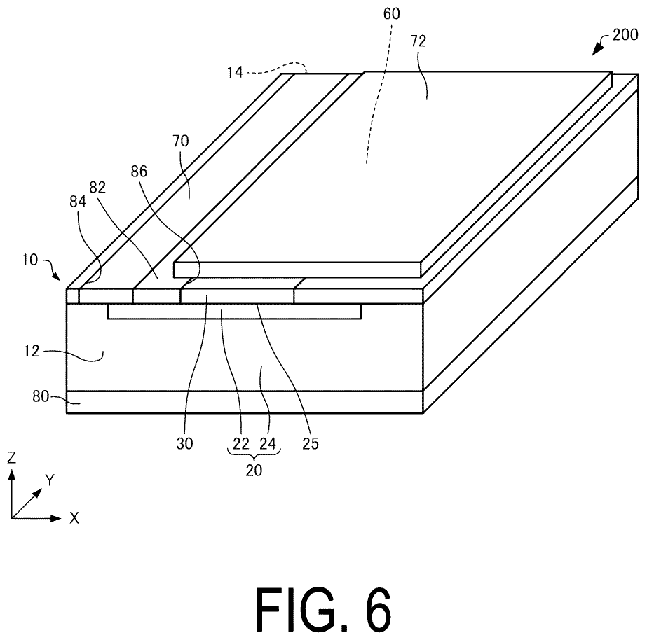

Next, a light emitting device according to a first modification example of the embodiment is described with reference to the drawings. FIG. 6 is a perspective view schematically illustrating a light emitting device 200 according to a first modification example of the embodiment. In the following description, in the light emitting device 200 according to the first modification example of the embodiment, members having the same functions as the constituent members of the light emitting device 100 according to the embodiment described above are denoted by the same reference signs, and detailed description thereof is omitted.

As illustrated in FIG. 1, in the light emitting device 100, the first electrode 70 and the second electrode 72 include a double-face electrode structure that sandwiches the light emitting waveguide layer 10.

In contrast, as illustrated in FIG. 6, in the light emitting device 200, the first electrode 70 and the second electrode 72 include a single-face electrode structure provided to only one side of the light emitting waveguide layer 10. The first electrode 70 and the second electrode 72 are provided at the light emitting waveguide layer 10.

For example, the light emitting device 200 includes a first insulating layer 80 and a second insulating layer 82. The material of the first insulating layer 80 and the second insulating layer 82 is SiO₂ or SiN, for example. For example, the first insulating layer 80 and the second insulating layer 82 are formed by a CVD method.

The first insulating layer 80 is provided below the light emitting waveguide layer 10. The second insulating layer 82 is provided at the light emitting waveguide layer 10. For example, a first groove 84 and a second groove 86 are formed in the second insulating layer 82. In the illustrated example, the first groove 84 and the second groove 86 have a longitudinal direction in the Y-axis direction. The second semiconductor portion 30 is provided at the first groove 84. The first electrode 70 is provided at the second groove 86. The second insulating layer 82 is provided between the second semiconductor portion 30 and the first electrode 70. The first groove 84 and the second groove 86 are formed by subjecting the second semiconductor portion 30 to patterning. The patterning is performed by, for example, photolithography and etching.

Due to the difference between the refractive index of the second insulating layer 82 and the refractive index of the second semiconductor portion 30, an effective refractive index difference occurs in the X-axis direction in the light emitting waveguide layer 10. The light generated at the pn junction 25 is actively guided through a region of the light emitting waveguide layer 10, which overlaps with the second semiconductor portion 30, as viewed in the Z-axis direction.

Due to the difference between the refractive index of the first insulating layer 80 and the refractive index of the light emitting waveguide layer 10 and the difference between the refractive index of the second insulating layer 82 and the refractive index of the light emitting waveguide layer 10, an effective refractive index difference occurs in the Z-axis direction in the light emitting device 200. The light generated at the pn junction 25 is actively guided through the light emitting waveguide layer 10.

The second layer 24 of the first semiconductor portion 20 may be configured by a u-type semiconductor. With this, the loss of light guided through the light emitting waveguide layer 10, which is caused by the second layer 24, can be reduced. The second layer 24 may be configured by an i-type semiconductor formed of an intrinsic semiconductor. Note that, when the second layer 24 is configured by an n-type semiconductor, the first semiconductor portion 20 may be configured only by the second layer 24 without providing the first layer 22. Note that the u-type semiconductor is a semiconductor that is not doped with impurities intentionally.

In a method of manufacturing the light emitting device 200, an electrode, which is omitted in illustration, may be temporarily formed below the first semiconductor portion 20, and then DPP annealing may be performed. After the electrode is peeled off, the first insulating layer 80 may be formed. The first insulating layer 80 may be formed after polishing the lower surface of the light emitting waveguide layer 10.

In the light emitting device 200, the opening portion 74 is not provided to the second electrode 72. With this, the manufacturing step of the light emitting device 200 can be shortened. As the second pixel electrode 72, a transparent electrode made of indium tin oxide (ITO) or the like is used. However, the second electrode 72 may be provided with the opening portion 74 in consideration of light absorption of the second electrode 72.

### 3.2. Second Modification Example

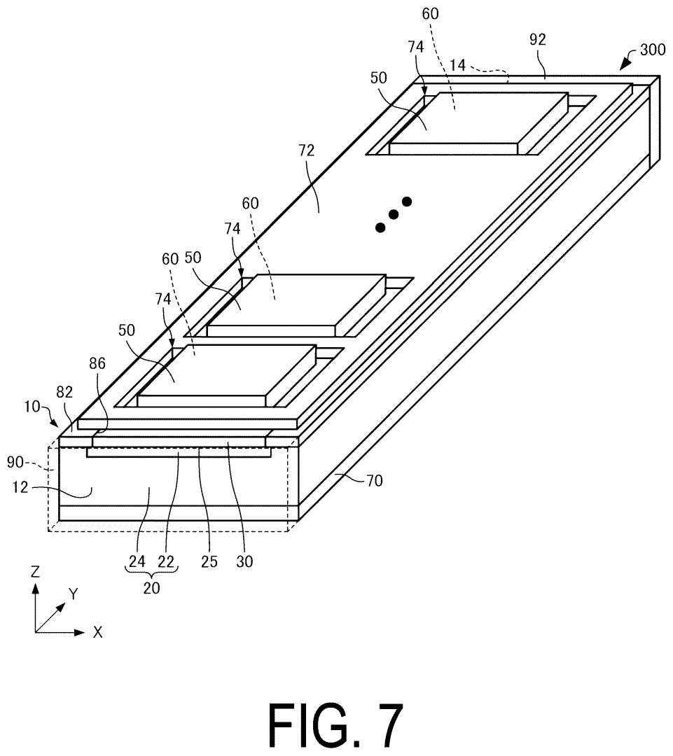

Next, a light emitting device according to a second modification example of the embodiment is described with reference to the drawings. FIG. 7 is a perspective view schematically illustrating a light emitting device 300 according to the second modification example of the embodiment. In the following description, in the light emitting device 300 according to the second modification example of the embodiment, members having the same functions as the constituent members of the light emitting devices 100 and 200 described above are denoted by the same reference signs, and detailed description thereof is omitted.

As illustrated in FIG. 1, in the light emitting device 100, only one opening portion 74 is provided.

In contrast, as illustrated in FIG. 7, in the light emitting device 300, the plurality of opening portions 74 are provided.

The plurality of opening portions 74 are provided in the first direction being the longitudinal direction of the light emitting waveguide layer 10. In the illustrated example, the plurality of opening portions 74 are arrayed in the Y-axis direction. The number of opening portions 74 is not particularly limited, and may be equal to or more than 100 and equal to or less than 100,000, desirably, equal to or more than 1,000 and equal to or less than 10,000, for example. The length of the light emitting waveguide layer 10 in the Y-axis direction is, for example, equal to or larger than 10 μm and equal to or smaller than 100 mm, desirably, equal to or larger than 100 μm and equal to or smaller than 70 mm, more desirably, equal to or larger than 1 mm and equal to or smaller than 50 mm. A voltage applied between the first electrode 70 and the second electrode 72 is equal to or more than 1 W and equal to or less than 1 kW, for example.

The plurality of cover layers 50 are provided in the first direction. The plurality of cover layers 50 are provided so as to correspond to the opening portions 74. In the illustrated example, the plurality of cover layers 50 are arrayed in the Y-axis direction. The plurality of optical portions 60 are provided in the first direction. The plurality of optical portions 60 are provided so as to correspond to the opening portions 74. In the illustrated example, the plurality of optical portions 60 are arrayed in the Y-axis direction. The plurality of third semiconductor portions 40 are provided in the first direction. The plurality of third semiconductor portions 40 are provided so as to correspond to the opening portions 74. In the illustrated example, the plurality of third semiconductor portions 40 are arrayed in the Y-axis direction.

For example, the light emitting device 300 includes a first high reflection film 90 and a second high reflection film 92.

The first high reflection film 90 is provided to the first side surface 12. The first high reflection film 90 covers the first side surface 12. For example, the first high reflection film 90 is an SiO₂ layer, a Ta₂O₅ layer, an Al₂O₃ layer, a TiN layer, a TiO₂ layer, an SiON layer, a SiN layer, or a multilayer film of those. The first high reflection film 90 is capable of increasing the reflectance of the first side surface 12 with respect to the light guided through the light emitting waveguide layer 10.

The second high reflection film 92 is provided to the second side surface 14. The second high reflection film 92 covers the second side surface 14. The material of the second high reflection film 92 is the same as the material of the first high reflection film 90, for example. The second high reflection film 92 is capable of increasing the reflectance of the second side surface 14 with respect to the light guided through the light emitting waveguide layer 10. With the first high reflection film 90 and the second high reflection film 92, the light guided through the light emitting waveguide layer 10 can easily laser-oscillate. The first high reflection film 90 and the second high reflection film 92 are formed by a CVD method, a sputtering method, a vacuum deposition method, or the like.

Note that, when the light emitting device 300 is used in a projector, the materials of the first high reflection film 90 and the second high reflection film 92 may be commonly shared for the red light, the green light, and the blue light, or may be different from each other according to the respective colors.

In the light emitting device 300, the plurality of opening portions 74 are provided in the first direction, and the plurality of optical portions 60 are provided in the first direction. Thus, in the light emitting device 300, light can be emitted through the plurality of opening portions 74. Further, the size of the light emitting waveguide layer 10 in the first direction is increased, and hence the light guided through the light emitting waveguide layer 10 can sufficiently be amplified. Further, when the light emitting device 300 is used in a projector, each of the plurality of opening portions 74 can constitute a pixel. Therefore, one light emitting device 300 can constitute a plurality of pixels.

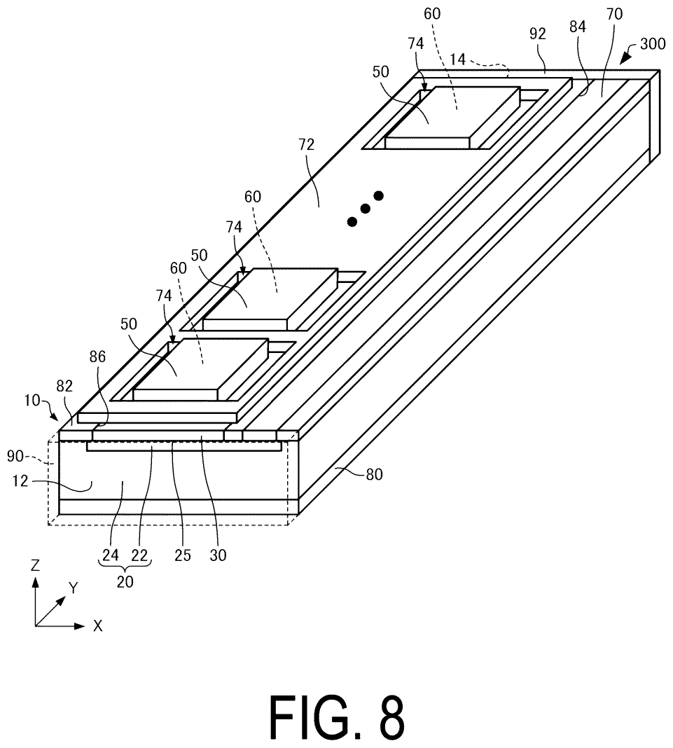

Note that, in the example illustrated in FIG. 7, the light emitting device 300 includes a double-face electrode structure. In contrast, as illustrated in FIG. 8, the light emitting device 300 may include a single-face electrode structure.

### 4. Light Source Module

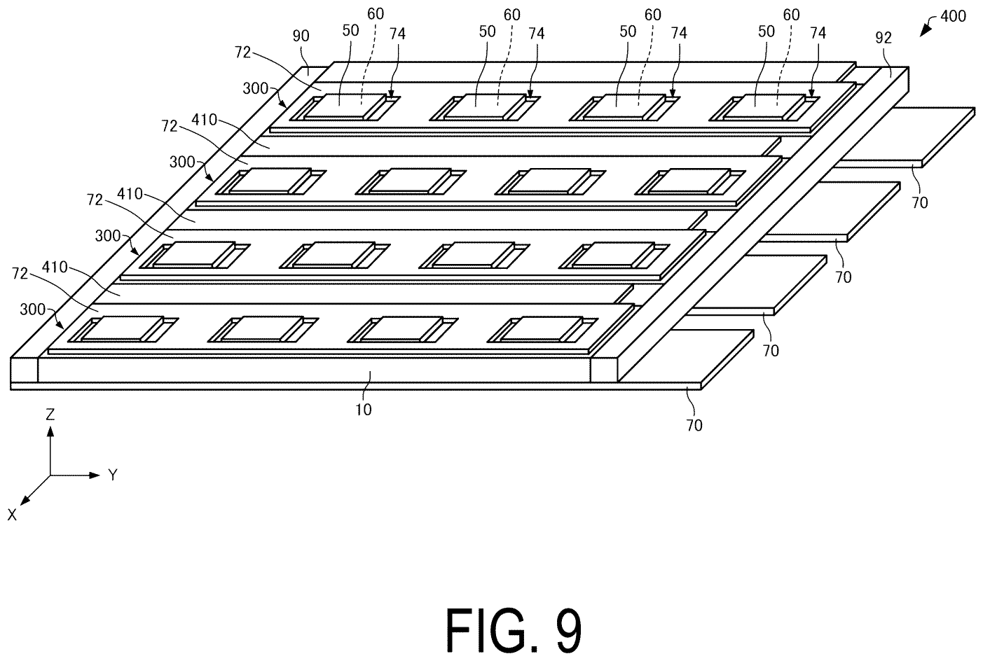

Next, a light source module according to the embodiment is described with reference to the drawings. FIG. 9 is a perspective view schematically illustrating a light source module 400 according to the embodiment.

As illustrated in FIG. 9, the light source module 400 includes a plurality of light emitting devices 300, for example.

The plurality of light emitting devices 300 are arrayed in a direction orthogonal to the longitudinal direction of the light emitting waveguide layer 10 as viewed in the Z-axis direction. In the illustrated example, the plurality of light emitting devices 300 are arrayed in the X-axis direction. In the light source module 400, the opening portions 74 are arrayed in a matrix in the X-axis direction and the Y-axis direction.

In the light emitting devices 300 adjacent to each other, the first high reflection films 90 are continuous. In the light emitting devices 300 adjacent to each other, the second high reflection films 92 are continuous. In the illustrated example, between the light emitting devices 300 adjacent to each other, a spacer member 410 is provided. The material of the spacer member 410 is SiO: or SiN, for example.

For example, in the light source module 400, the light emitting device 300 that emits the red light, the light emitting device 300 that emits the green light, and the light emitting device 300 that emits the blue light are arrayed in the X-axis direction in the stated order. With this, with the light source module 400, red light, green light, and blue light can be emitted. The wavelength of the light emitted from the light emitting device 300 is adjusted by the material of the light emitting waveguide layer 10, the size of the light emitting waveguide layer 10 in the Y-axis direction, or the like.

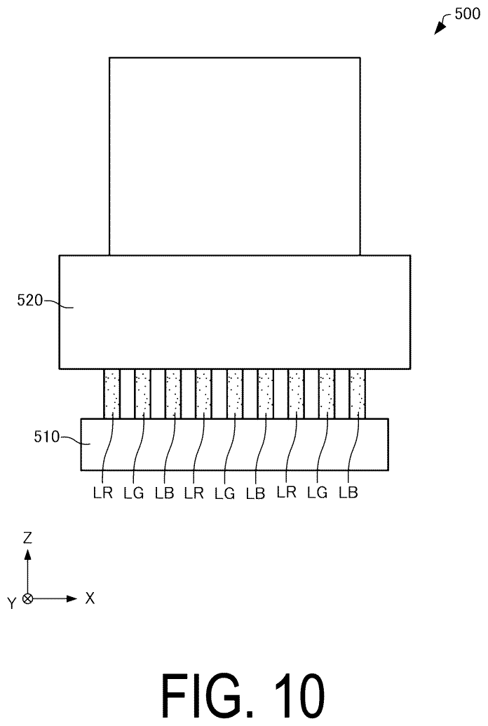

Note that the light source module 400 may be configured so that the plurality of light emitting devices 300 emit only one type of color light. Further, in the example illustrated in FIG. 9, the light source module 400 includes a double-face electrode structure. In contrast, as illustrated in FIG. 10, the light source module 400 may include a single-face electrode structure.

### 5. Projector

Next, a projector according to the embodiment is described with reference to the drawings. FIG. 10 is a view schematically illustrating a projector 500 according to the embodiment.

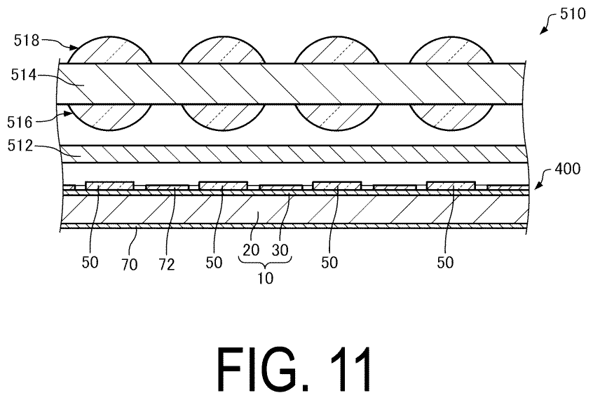

As illustrated in FIG. 10, for example, the projector 500 includes a light emitting mechanism 510 and a projection lens 520. The light emitting mechanism 510 emits light toward the projection lens 520. In the illustrated example, the light emitting mechanism 510 emits light in the Z-axis direction. The light emitting mechanism 510 is configured to emit red light LR, green light LG, and blue light LB. Here, FIG. 11 is a cross-sectional view schematically illustrating the light emitting mechanism 510. As illustrated in FIG. 11, for example, the light emitting mechanism 510 includes the light source module 400, an optical element 512, an optical modulation element 514, a first micro-lens array 516, and a second micro-lens array 518.

The light source module 400 is configured to emit the red light LR, the green light LG, and the blue light LB.

The light from the light source module 400 enters the optical element 512. The optical element 512 polarizes the light from the light source module 400. The optical element 512 is a polarizer such as a polarization beam splitter.

The light from the optical element 512 enters the optical modulation element 514. The optical modulation element 514 modulates the incident light in accordance with image information. The optical modulation element 514 is a transmissive liquid crystal light valve, for example.

For example, the first micro-lens array 516 is provided to the surface of the optical modulation element 514 on the optical element 512 side. The first micro-lens array 516 is configured by a plurality of micro-lenses. For example, the second micro-lens array 518 is provided to the surface of the optical modulation element 514 on a side opposite to the optical element 512. The second micro-lens array 518 is configured by a plurality of micro-lenses. The micro-lens arrays 516 and 518 concentrate the incident light.

Note that, when the radiation angle of the light emitted from the light source module 400 is sufficiently small, the micro-lens arrays 516 and 518 may not be provided. Further, a uniform illumination system such as a homogenizer, which is omitted in illustration, may be provided.

The light from the second micro-lens array 518 enters the projection lens 520. The projection lens 520 enlarges an image formed by the optical modulation element 514, and projects the image on a screen, which is omitted in illustration.

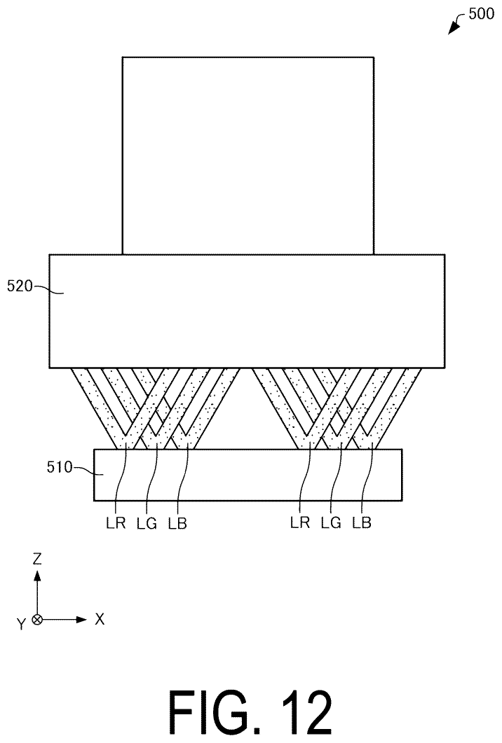

Note that, as illustrated in FIG. 12, the light source module 400 of the light emitting mechanism 510 may be configured to emit light to two directions at 60 degrees and 120 degrees with respect to the +X-axis direction. With this, the number of light emitting devices 300 in the light source module 400 can be reduced. The direction of the light emitted from the light emitting device 300 can be adjusted by designing the optical portion 60 of the light emitting device 300 as appropriate. In particular, when the optical portion 60 is configured by a grating or a two-dimensional photonic crystal, the light emission direction is easily adjusted. Alternatively, the light source module 400 may be configured to emit light to three directions at 45 degrees, 90 degrees, and 135 degrees with respect to the +X-axis direction. Alternatively, the light source module 400 may emit light to two directions at 60 degrees and 120 degrees with respect to the +X-axis direction and emit light to two directions at 60 degrees and 120 degrees with respect to the +Y-axis direction.

In this manner, the number of light emission directions of the light source module 400 is not particularly limited. However, the number of light emission directions may be reduced in consideration of energy efficiency, noise reduction, and contrast improvement of the light source module 400, which are achieved by light emission corresponding to a pixel with a minimum light amount in the light waveguide direction.

### 6. Modified Examples of Projector

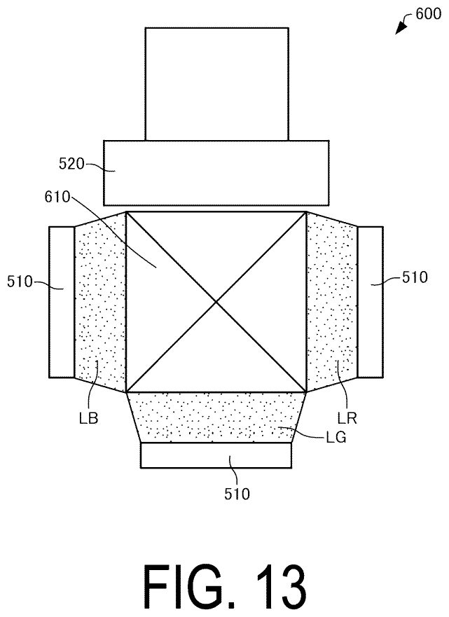

Next, a projector according to a modification example of the embodiment is described with reference to the drawings. FIG. 13 is a view schematically illustrating a projector 600 according to the modification example of the embodiment. In the following description, in the projector 600 according to the modification example of the embodiment, members having the same functions as the constituent members of the projector 500 described above are denoted by the same reference numerals, and detailed description thereof is omitted.

As illustrated in FIG. 10, in the projector 500, only one light emitting mechanism 510 is provided, and the one light emitting mechanism 510 emits the red light LR, the green light LG, and the blue light LB.

In contrast, as illustrated in FIG. 13, in the projector 600, three light emitting mechanisms 510 are provided, and the three light emitting mechanisms 510 emit the red light LR, the green light LG, and the blue light LB, respectively.

The projector 600 includes a cross dichroic prism 610. The color light emitted from the three light emitting mechanisms 510 enters the cross dichroic prism 610. The cross dichroic prism 610 is formed by bonding four right-angle prisms. The cross dichroic prism 610 includes a dielectric multilayer film that reflects the red color light and a dielectric multilayer film that reflects the blue color light. The light beams of the three colors are synthesized by the dielectric multilayer films, and light representing a color image is formed. The synthesized light enters the projection lens 520.

The embodiment and the modification examples described above are merely examples, and are not intended as limiting. For example, each embodiment and each modification example can also be combined together as appropriate.

The present disclosure includes configurations that are substantially identical to the configurations described in the embodiment, for example, configurations with identical functions, methods and results, or with identical objects and effects. Also, the present disclosure includes configurations obtained by replacing non-essential portions of the configurations described in the embodiment. In addition, the present disclosure includes configurations having the same operations and effects or can achieve the same objects as the configurations described in the embodiment. Further, the present disclosure includes configurations obtained by adding known techniques to the configurations described in the embodiment.

The following contents are derived from the embodiment and the modification examples described above.

A light emitting device according to one aspect includes a light emitting waveguide layer including a first semiconductor portion being configured by an indirect transition semiconductor and a second semiconductor portion being configured by an indirect transition semiconductor, having a conductive type different from the first semiconductor portion, and forming a pn junction with the first semiconductor portion, an electrode being provided to the second semiconductor portion on a side opposite to the first semiconductor portion and injecting an electric current into the pn junction, and at least one optical portion, wherein the light emitting waveguide layer has a longitudinal direction in a first direction, the light emitting waveguide layer generates, at the pn junction, light having an energy smaller than a band gap energy of the semiconductors constituting the first semiconductor portion and the second semiconductor portion, and causes the light being generated to resonate in the first direction, and the optical portion emits the resonating light to a second direction intersecting with the first direction.

According to the light emitting device, light emittance efficiency can be improved.

In the light emitting device according one aspect, the electrode may be provided with at least one opening portion through which light advancing in the second direction passes.

According to the light emitting device, the loss of light caused by the second electrode can be reduced.

The light emitting device according one aspect may include a cover layer being provided to the opening portion and covering the light emitting waveguide layer.

According to the light emitting device, the cover layer can protect the light emitting waveguide layer from moisture or the like.

In the light emitting device according one aspect, the optical portion may be provided to the cover layer.

According to the light emitting device, the loss of light guided through the light emitting waveguide layer, which is caused by the optical portion, can be reduced.

In the light emitting device according one aspect, a plurality of the opening portions may be provided in the first direction, and a plurality of the optical portions may be provided in the first direction.

According to the light emitting device, light can be emitted through the plurality of opening portions.

In the light emitting device according one aspect, the first semiconductor portion may include a first layer and a second layer having an impurity concentration lower than the first layer, and the first layer may be formed between the second layer and the second semiconductor portion and form the pn junction.

According to the light emitting device, the loss of light guided through the light emitting waveguide layer, which is caused by the second layer, can be reduced.

In the light emitting device according one aspect, the semiconductors constituting the first semiconductor portion and the second semiconductor portion may be Si, and the light emitting waveguide layer may generate infrared light.

According to the light emitting device, infrared light can be emitted.

In the light emitting device according one aspect, the semiconductors constituting the first semiconductor portion and the second semiconductor portion may be SiC, and the light emitting waveguide layer may generate visible light.

According to the light emitting device, visible light can be emitted.

In the light emitting device according one aspect, the semiconductors constituting the first semiconductor portion and the second semiconductor portion may be GaP, and the light emitting waveguide layer may generate red light.

According to the light emitting device, red light can be emitted.

In the light emitting device according one aspect, the light emitting waveguide layer may include a third semiconductor portion provided between the second semiconductor portion and the cover layer, and an impurity concentration of the third semiconductor portion may be lower than an impurity concentration of the second semiconductor portion.

According to the light emitting device, the loss of light caused by the third electrode can be reduced.

A projector according to one aspect includes the light emitting device according to one aspect.

What is claimed is:

1. A light emitting device comprising:
a light emitting waveguide layer including:
a first semiconductor portion being configured by an indirect transition semiconductor; and
a second semiconductor portion being configured by an indirect transition semiconductor, having a conductive type different from the first semiconductor portion, and forming a pn junction with the first semiconductor portion;
an electrode being provided to the second semiconductor portion on a side opposite to the first semiconductor portion and injecting an electric current into the pn junction; and
at least one optical portion, wherein
the light emitting waveguide layer has a longitudinal direction in a first direction,
the light emitting waveguide layer generates, at the pn junction, light having an energy smaller than a band gap energy of the semiconductors constituting the first semiconductor portion and the second semiconductor portion, and causes the light being generated to resonate in the first direction, and
the optical portion emits the resonating light to a second direction intersecting with the first direction.

2. The light emitting device according to claim 1, wherein
the electrode is provided with at least one opening portion through which light advancing in the second direction passes.

3. The light emitting device according to claim 2 comprising:
a cover layer being provided to the opening portion and covering the light emitting waveguide layer.

4. The light emitting device according to claim 3, wherein
the optical portion is provided to the cover layer.

5. The light emitting device according to claim 2, wherein
a plurality of the opening portions are provided in the first direction, and
a plurality of the optical portions are provided in the first direction.

6. The light emitting device according to claim 1, wherein
the first semiconductor portion includes:
a first layer; and
a second layer having an impurity concentration lower than the first layer, and
the first layer is formed between the second layer and the second semiconductor portion, and forms the pn junction.

7. The light emitting device according to claim 1, wherein
the semiconductors constituting the first semiconductor portion and the second semiconductor portion are Si, and
the light emitting waveguide layer generates infrared light.

8. The light emitting device according to claim 1, wherein
the semiconductors constituting the first semiconductor portion and the second semiconductor portion are SiC, and
the light emitting waveguide layer generates visible light.

9. The light emitting device according to claim 1, wherein
the semiconductors constituting the first semiconductor portion and the second semiconductor portion are GaP, and
the light emitting waveguide layer generates red light.

10. The light emitting device according to claim 3, wherein
the light emitting waveguide layer includes a third semiconductor portion provided between the second semiconductor portion and the cover layer, and
an impurity concentration of the third semiconductor portion is lower than an impurity concentration of the second semiconductor portion.

11. A projector comprising the light emitting device according to claim 1.
